(19) United States
(12) Patent Application Publication
(10) Pub. No.: US 2026/0173912 A1
(43) Pub. Date: Jun. 18, 2026

(54) ELECTRONIC DEVICE, INTERPOSER AND METHOD FOR MANUFACTURING THE SAME

(71) Applicants: Innolux Corporation, Miaoli County (TW); nD-HI Technologies Lab, Inc., Taipei City (TW)

(72) Inventors: Ho-Ming Tong, Taipei City (TW); Chun-Yu Chien, Miaoli County (TW); Chih-Chao Chuang, Miaoli County (TW); Ching-Yu Chu, Miaoli County (TW); Shu-Hsien Wu, Miaoli County (TW); Tsung-Yuan Wu, Miaoli County (TW)

(73) Assignees: Innolux Corporation, Miaoli County (TW); nD-HI Technologies Lab, Inc., Taipei City (TW)

(21) Appl. No.: 19/399,676

(22) Filed: Nov. 25, 2025

Related U.S. Application Data
(60) Provisional application No. 63/734,189, filed on Dec. 16, 2024.
(60) Provisional application No. 63/734,192, filed on Dec. 16, 2024.

(30) Foreign Application Priority Data
Jul. 18, 2025 (CN) 202510996179.9

(51) Int. Cl. H01L 23/538; H01L 21/48; H01L 23/00; H01L 23/373; H01L 25/065

(52) U.S. Cl. CPC H10W 70/611; H10W 40/258; H10W 70/05; H10W 70/65; H10W 90/401; H10W 90/00; H10W 90/724

(57) ABSTRACT

The present disclosure provides an electronic device, an interposer and a method for manufacturing the same. The interposer includes a package structure including a plurality of connection units spaced apart from each other and arranged in an array, a first package layer surrounding the plurality of connection units, and a first circuit structure disposed at a first side of the first package layer and electrically connected to the plurality of connection units. Each connection unit includes a base layer and a first conductive element disposed in the base layer.

### CROSS-REFERENCE TO RELATED APPLICATION

This application claims the priority benefit of U.S. provisional application Ser. No. 63/734,192, filed on Dec. 16, 2024, U.S. provisional application Ser. No. 63/734,189, filed on Dec. 16, 2024, and China application serial no. 202510996179.9, filed on Jul. 18, 2025. The entirety of each of the above-mentioned patent applications is hereby incorporated by reference herein and made a part of this specification.

### BACKGROUND

### Technical Field

The present invention relates to an electronic device, an interposer, and a method for manufacturing the same, and particularly relates to an electronic device, an interposer, and a method for manufacturing the same that are beneficial for improving reliability.

### Description of Related Art

With the continuous development of electronic devices toward lighter, thinner, shorter, and smaller aspects and the continuously increasing performance requirements of users for electronic devices, the integration degree of various electronic elements (such as chips) in electronic devices also needs to be increased accordingly. Generally, various electronic elements and/or various packages including various electronic elements usually have different wiring densities, pitches, or dimensions, and in some cases may not be compatible with each other. Therefore, disposing various electronic elements and/or various packages including various electronic elements on an interposer substrate or adding one or more interposer substrates between them is one of the means to address the above problems.

However, the coefficient of thermal expansion (CTE) of various electronic elements and/or various packages including various electronic elements may not be compatible with the material used for the interposer substrate in some cases, causing thermal stress generated during subsequent high-temperature processes such as reflow to damage (such as cracks) various electronic elements and/or various packages including various electronic elements, making it difficult to meet current or future reliability requirements for electronic devices.

### SUMMARY

The present disclosure provides an electronic device, an interposer, and a method for manufacturing the same, which are beneficial for improving the reliability of the electronic device.

According to an embodiment of the present disclosure, an interposer includes a package structure including a plurality of connection units, a first packaging layer, and a first circuit structure. The plurality of connection units are spaced apart from each other and arranged in an array, wherein each connection unit includes a substrate layer and a first conductive element disposed in the substrate layer. The first packaging layer surrounds the plurality of connection units and includes a portion disposed between the plurality of connection units. The first circuit structure is disposed at a first side of the first packaging layer and electrically connected to the plurality of connection units.

According to an embodiment of the present disclosure, an electronic device includes an interposer, a plurality of electronic units, and an external component. The interposer includes a package structure and a second circuit structure. The package structure includes a plurality of connection units, a first packaging layer, and a first circuit structure. The plurality of connection units are spaced apart from each other and arranged in an array, wherein each connection unit includes a substrate layer and a first conductive element disposed in the substrate layer. The first packaging layer encapsulates the plurality of connection units and includes a portion disposed between the plurality of connection units. The first circuit structure is disposed on a first side of the first packaging layer and electrically connected to the plurality of connection units. The second circuit structure is disposed on a second side of the first packaging layer opposite to the first side and electrically connected to the plurality of connection units. The plurality of electronic units are disposed on the second circuit structure and electrically connected to the second circuit structure. The external component is disposed under the first circuit structure and electrically connected to the first circuit structure.

According to an embodiment of the present disclosure, a method for manufacturing an interposer includes the following steps. A plurality of connection units are disposed on a first circuit structure in an array, wherein the plurality of connection units are electrically connected to the first circuit structure, and each connection unit includes a substrate layer and a first conductive element disposed in the substrate layer. A first underfill is provided between the first circuit structure and the substrate layer. A first packaging layer encapsulating the plurality of connection units is provided on the first underfill to form a package structure, wherein the first packaging layer includes a portion formed between the plurality of connection units.

Based on the above, in the embodiments of the present disclosure, the first packaging layer surrounds the plurality of connection units that are spaced apart from each other and arranged in an array and includes a portion disposed between the plurality of connection units, which can mitigate the difference in coefficient of thermal expansion (CTE) between the substrate layer of the connection units and the other various electronic elements and/or the various packages including the various electronic elements, thereby improving the reliability of the interposer and/or the electronic device including the interposer.

To make the features and advantages of the disclosure more comprehensible, several embodiments accompanied with drawings are described in detail as follows.

### BRIEF DESCRIPTION OF THE DRAWINGS

The drawings are included for further understanding of the disclosure, and the drawings are incorporated into and constitute a part of the present specification. The drawings illustrate embodiments of the disclosure and, together with the description, are used to explain the principles of the disclosure.

FIG. 1 to FIG. 5B are schematic views of a method manufacturing an electronic device according to a first embodiment of the present disclosure.

FIG. 6 is a schematic cross-sectional view of an electronic device according to a second embodiment of the present disclosure.

FIG. 7A and FIG. 7B are respectively a schematic cross-sectional view and a schematic top view of an electronic device according to a third embodiment of the present disclosure.

FIG. 8 is a schematic cross-sectional view of an electronic device according to a fourth embodiment of the present disclosure.

FIG. 9A to FIG. 9C are schematic cross-sectional views of interposers according to different embodiments of the present disclosure.

### DESCRIPTION OF THE EMBODIMENTS

The disclosure may be understood by referring to the following detailed description in conjunction with the drawings. It should be noted that, in order to allow readers to easily understand and for the sake of simplicity of the drawings, multiple drawings in the disclosure show just a part of a package structure, and specific elements in the drawings are not drawn according to actual proportions. In addition, the quantity and size of elements in the drawings are merely illustrative and are not intended to limit the scope of the disclosure. For example, for the sake of clarity, relative sizes, thicknesses, and positions of respective film layers, regions, and/or structures may be reduced or enlarged.

Throughout the present specification and the appended claims, certain terms are used to refer to specific elements. A person skilled in the art should understand that manufacturers of electronic devices may refer to the same elements by different names. This document does not intend to distinguish elements that have the same function but different names. In the following description and the claims, words such as “have” and “comprise” are open-ended terms, and therefore should be interpreted as meaning “including but not limited to . . . ”.

In this document, “an element is disposed on another element” is used to conveniently describe the relative position between the element and another element, and is not intended to limit the process steps or sequence of the element and another element.

Directional terms mentioned in the present document, such as “upper,” “lower,” “front,” “rear,” “left,” “right,” and the like, are for referencing the directions shown in the drawings. Therefore, the directional terms used are for explanation and are not intended to limit the disclosure. It should be understood that when an element or a film layer is described as being “on” another element or film layer or “connected to” another element or film layer, the element or film layer may be directly on or directly connected to another element or film layer, or there may be an intervening element or film layer (i.e., an indirect case) between the two. Conversely, when an element or film layer is described as being “directly” on another element or film layer or “directly connected to” another element or film layer, no intervening element or film layer exists between the two. In addition, when an element or film layer is described as overlapped with another element or film layer, the element or film layer at least partially overlaps another element or film layer.

The terms “about,” “approximately,” “substantially,” or “roughly” mentioned in the present document generally represent being within 10% of a given value or range, or being within 5%, or 0.5% of the given value or range. In addition, the phrase “a given range is from a first value to a second value” or “a given range falls within a range from a first value to a second value” means that the given range includes the first value, the second value, and other values between them.

In some embodiments of the disclosure, bonding or connection terms such as “connected,” “interconnected,” and the like, unless otherwise specifically defined, may refer to a case where two structures are in direct contact or may refer to a case where two structures are not in direct contact and there is another structure disposed between the two structures. Bonding or connection terms may also include cases where both structures are movable or both structures are fixed. In addition, the terms “electrically connected” and “coupled to” include any direct and indirect electrical connection means.

In the following embodiments, the same or similar elements will be denoted by the same or similar reference numerals or symbols, and redundant descriptions thereof will be omitted. In addition, features in different embodiments may be arbitrarily combined and used as long as they do not violate or conflict with the spirit of the invention, and simple equivalent changes and modifications made according to the present specification or the claims still fall within the scope of the disclosure. That is, the following embodiments may involve replacing, reorganizing, or combining technical features of several different embodiments to achieve other embodiments without departing from the spirit of the disclosure. Furthermore, the terms “first,” “second,” and the like mentioned in the present specification or the claims are merely used to designate different elements or distinguish different embodiments or ranges, and are not intended to limit an upper or lower limit on the number of elements, nor are they intended to limit a manufacturing sequence or arrangement order of elements.

In the present disclosure, the roughness, the thickness, length, and width may be obtained through a measurement using an optical microscope (OM) and/or an electron microscope such as a scanning electron microscope (SEM) or a transmission electron microscope (TEM), but are not limited thereto.

The electronic device of the present disclosure may be applied to, for example, a wafer-level package (WLP) process, such as a process including a chip-on-wafer-on-substrate (CoWoS) technique, but is not limited thereto. Alternatively, the electronic device of the present disclosure may be applied to, for example, a panel-level package (PLP) process, such as a process including a chip-on-panel-on-substrate (CoPoS) technique, but is not limited thereto. In some embodiments, the manufacturing process of the electronic device in the present disclosure may be applied, for example, to a chip-last process or a chip-first process. The electronic device described in the present disclosure may be applied to high-speed computing modules, power modules, semiconductor package devices, optical communication modules, display devices, light-emitting devices, backlight devices, antenna devices, sensing devices, or tiled devices, but is not limited thereto.

The exemplary embodiments of the present disclosure are now described in detail with reference to the drawings. Wherever possible, like reference numerals or symbols are used to denote the same or similar elements throughout the drawings and the description.

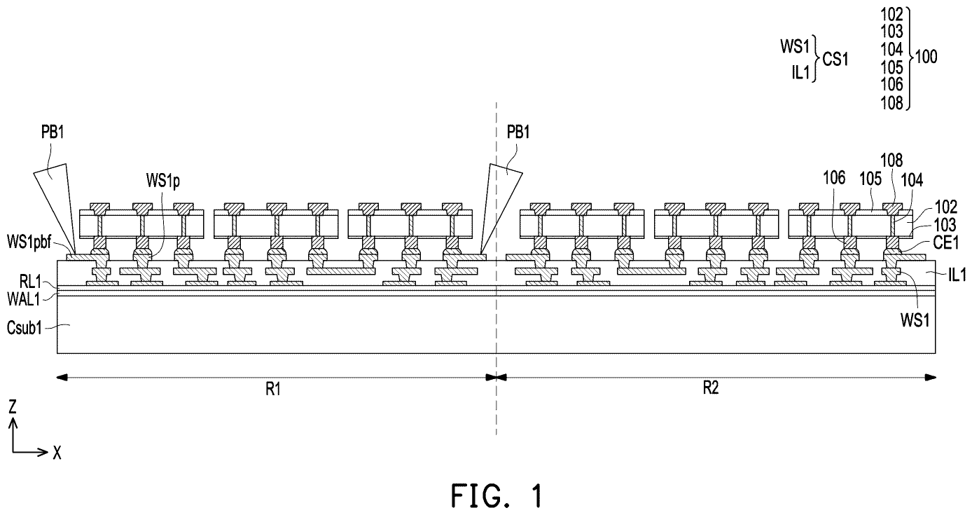

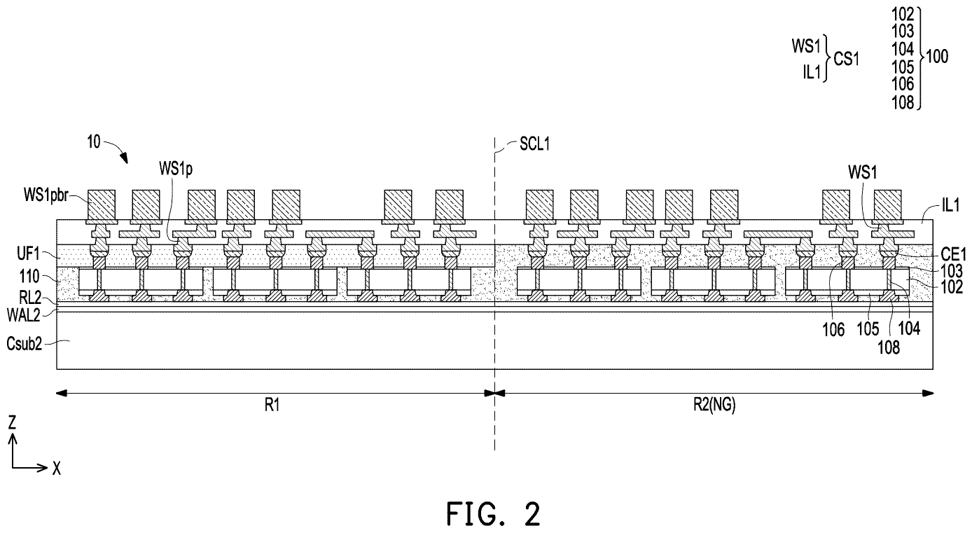

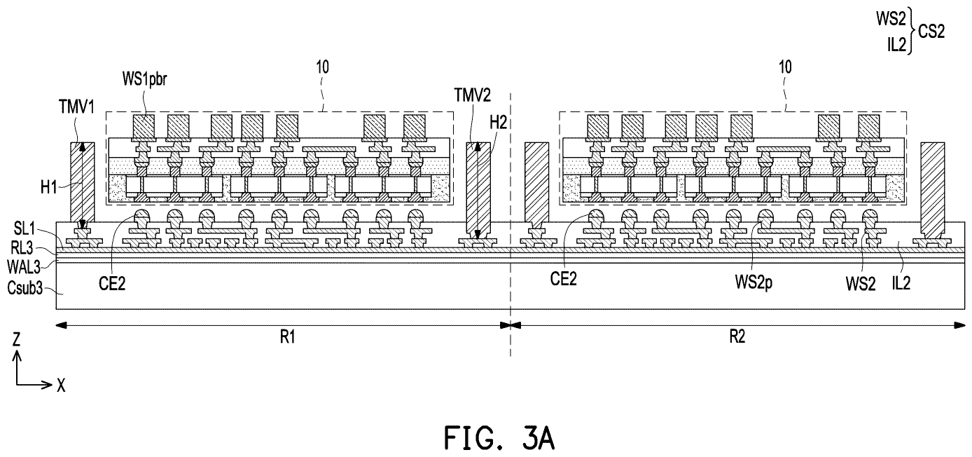

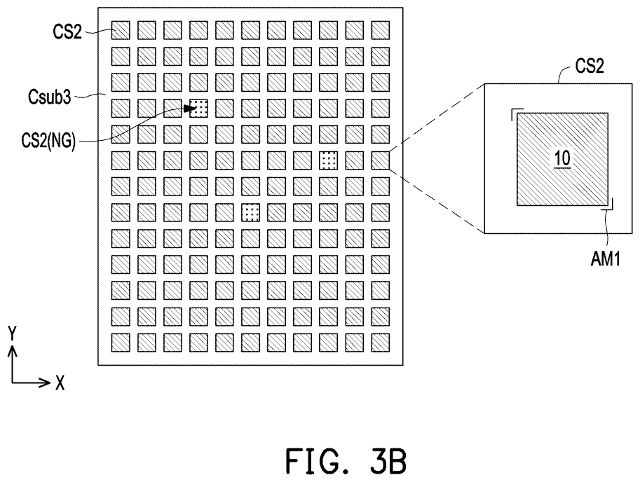

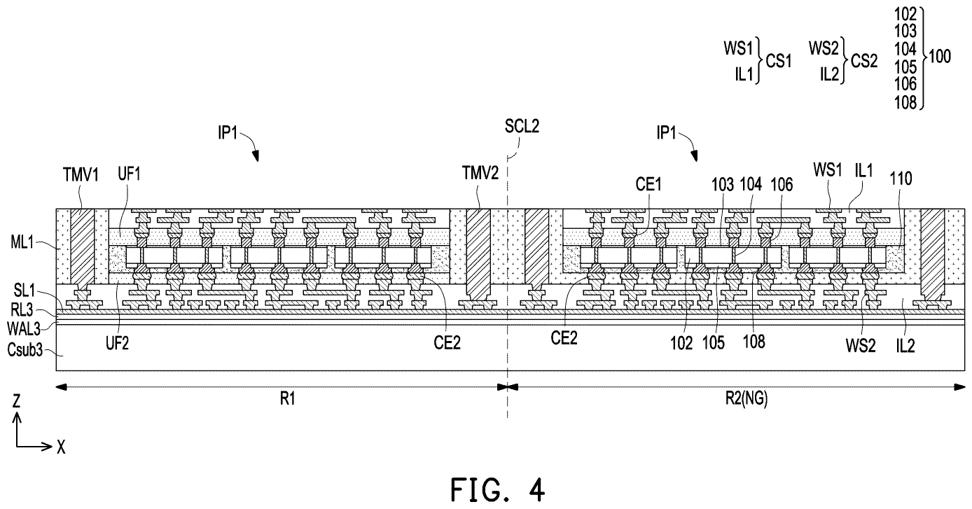

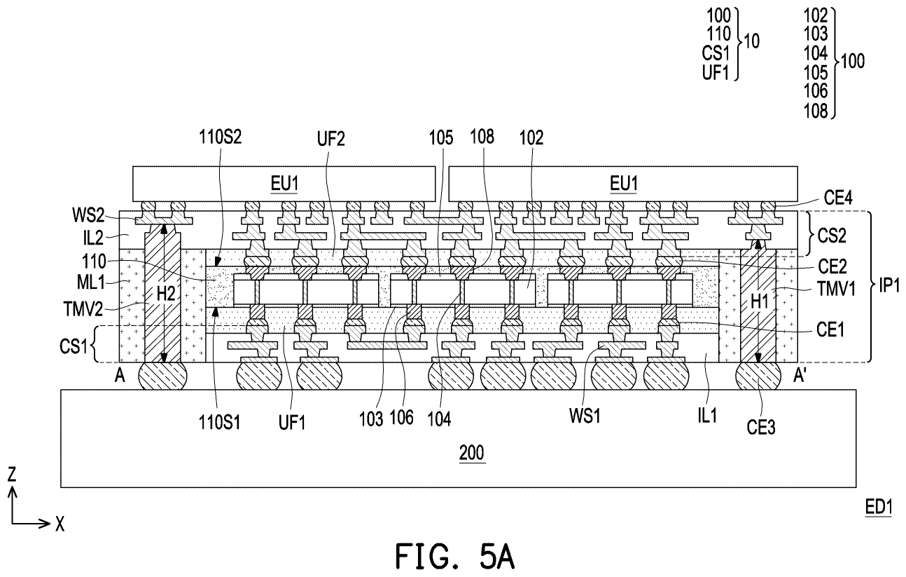

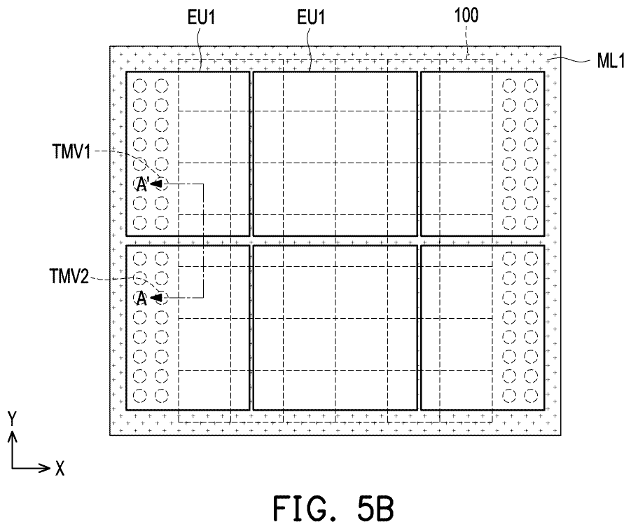

FIG. 1 to FIG. 5B are schematic views of a method manufacturing an electronic device according to a first embodiment of the present disclosure. FIG. 1, FIG. 2, FIG. 3A, FIG. 4, and FIG. 5A are schematic cross-sectional views, and FIG. 3B is a schematic top view in an embodiment corresponding to FIG. 3A, and FIG. 5B is a schematic top view in an embodiment of FIG. 5A, for example, FIG. 5A is corresponded to a schematic cross-sectional view taken along line A-A′ of FIG. 5B. For the convenience of illustration, FIG. 5B merely shows the connection unit 100, the electronic unit EU1, the second packaging layer ML1, and the conductive vias TMV1, TMV2.

In the present embodiment, the method for manufacturing the electronic device (e.g., the electronic device ED1 shown in FIG. 5A) may include the following steps.

First, referring to FIG. 1, a carrier Csub1 is provided. In some embodiments, the material of the carrier Csub1 may include glass, quartz, sapphire, ceramic, stainless steel, silicon wafer, other suitable substrate materials, or combinations thereof, but is not limited thereto. Next, an anti-warpage layer WAL1 and a release layer RL1 are sequentially formed on the carrier Csub1. In some embodiments, the anti-warpage layer WAL1 may be a single-layer or a multi-layer structure including organic materials and/or inorganic materials, wherein the inorganic materials may include silicon oxide (SiO₂), silicon nitride (SiₓN_{y}), silicon oxynitride (SiOₓN_{y}), or other suitable inorganic materials, but is not limited thereto. In some embodiments, the release layer RL1 may be a temporary bonding layer, which may include adhesive thermal-type or optical-type release materials, so that subsequently formed working units, elements, or film layers may be temporarily bonded to the release layer RL1. In other words, the release layer RL1 may assist in removing working units, elements, or film layers subsequently formed on the carrier Csub1 from the carrier Csub1. When thermal-type release materials are used to form the release layer RL1, the thermal-type release materials lose adhesiveness when heated, so that the elements or film layers formed thereon can be peeled off from the release layer RL1. For example, the release layer RL1 may be thermal release tape (TRT) or light-to-heat-conversion (LTHC) release coating. When optical-type release materials are used to form the release layer RL1, the optical-type release materials lose adhesiveness when exposed to radiation such as ultra-violet light (UV light), so that the elements or film layers formed thereon can be peeled off from the release layer RL1.

Then, a first circuit structure CS1 is provided on the release layer RL1. In this embodiment, the first circuit structure CS1 may include an insulation layer IL1 and a wiring structure WS1 formed in the insulation layer IL1. In some embodiments, the insulation layer IL1 may include a plurality of insulation layers alternately stacked along a vertical direction (e.g., Z direction). The wiring structure WS1 may include a plurality of conductive patterns/conductive layers and conductive vias formed in the insulation layer IL1 in which the conductive patterns/conductive layers are alternately stacked along the vertical direction, and conductive vias connecting the conductive patterns/conductive layers. The wiring structure WS1 may include any suitable conductive material, such as copper, titanium, nickel, combinations or alloys of the aforementioned materials, but is not limited thereto. The insulation layer IL1 may include organic materials or inorganic materials. The organic materials may include polyimide (PI), poly-p-xylylene (also known as Parylene), benzocyclobutene (BCB), epoxy resin, polycarbonate (PC), polyethylene terephthalate (PET), polyethylene naphthalate (PEN), polymers, or other suitable organic materials, but are not limited thereto. The inorganic materials may include silicon oxide, silicon nitride, silicon oxynitride, or other suitable inorganic materials, but are not limited thereto.

Thereafter, a plurality of connection units 100 are arranged on the first circuit structure CS1 in an array, wherein the plurality of connection units 100 are electrically connected to the first circuit structure CS1. In this embodiment, the wiring structure WS1 may include pads WS1p and pads WS1pbf electrically connected to the plurality of connection units 100 in which the pads WS1pbf may include test portions for performing detection, such that, after the connection units 100 are disposed on the first circuit structure CS1, an electrical testing may be performed by probing the test portions of the pads WS1pbf with probes PB1 to determine whether the electrical connection between the connection units 100 and the first circuit structure CS1 meets desired requirements. For example, the region R1 may be a region where the electrical connection between the connection units 100 and the first circuit structure CS1 meets the desired requirements, while the region R2 may be a region where the electrical connection between the connection units 100 and the first circuit structure CS1 does not meet the desired requirements. In some other embodiments, before the connection units 100 are arranged on the first circuit structure CS1, an electrical testing of the first circuit structure CS1 may also be performed by probing the test portions of the pads WS1pbf with the probes PB1 to determine whether there are portions of the first circuit structure CS1 that do not meet the desired requirements.

In this embodiment, each connection unit 100 includes a substrate layer 102 and a conductive element 104 disposed in the substrate layer 102. The substrate layer 102 may include polyimide, glass, silicon, organic material, inorganic material, or other suitable substrate materials. The conductive element 104 may include any suitable conductive material, such as copper, titanium, nickel, combinations or alloys of the above materials, but is not limited thereto. In this embodiment, the conductive element 104 may be a through substrate via (TSV) penetrating through the substrate layer 102.

In this embodiment, each connection unit 100 may further include insulation layers 103 and 105 and conductive elements 106 and 108 disposed at opposite sides of the substrate layer 102 in a vertical direction (e.g., Z direction). The insulation layers 103 and 105 may each include any suitable insulation material similar with the insulation layer IL1. The conductive elements 106 and 108 may each include any suitable conductive material, such as copper, titanium, nickel, combinations or alloys of the above materials, but are not limited thereto. In some embodiments, the conductive elements 106 and 108 may include copper pillars, but are not limited thereto.

In this embodiment, the connection units 100 may be bonded to the first circuit structure CS1 through connection elements CE1 disposed between the conductive elements 106 and the pads WS1p. The material of the connection element CE1 may include tin-silver (SnAg), tin, silver, nickel, gold, copper, conductive adhesive, or other suitable conductive materials, but is not limited thereto. The connection element CE1 may include a solder ball. In some embodiments, the connection element CE1 may be adopted to a controlled collapse chip connection bump (C4 bump).

Next, referring to FIG. 1 and FIG. 2 simultaneously, a first underfill UF1 is provided between the first circuit structure CS1 and the substrate layer 102 to ensure the signal transmission path between the connection units 100 and the first circuit structure CS1, thereby helping to improve the reliability of the electronic device. In this embodiment, the first underfill UF1 may surround the conductive elements 106, the connection elements CE1, and the pads WS1p. In this embodiment, “one component surrounding another component” may refer to that the component may be at least in contact with the side surface of another component in a cross-sectional view. For example, as shown in FIG. 2, the first underfill UF1 may be in contact with the side surfaces of the conductive elements 106, the connection elements CE1, and the pads WS1p.

In this embodiment, as shown in FIG. 2, the region R1 may be a region where the electrical connection between the connection units 100 and the first circuit structure CS1 meets desired requirements, while the region R2(NG) may be a region where the electrical connection between the connection units 100 and the first circuit structure CS1 does not meet desired requirements. In this case, the first underfill UF1 may only be formed in the region R1 that meets the desired requirements, and may not be formed in the region R2(NG) that does not meet the desired requirements, which is beneficial for saving process costs.

Then, a first packaging layer 110 surrounding the plurality of connection units 100 is provided on the first underfill UF1 to form a package structure 10. According to some embodiments, the first packaging layer 110 may surround the plurality of connection units 100, wherein a portion of the first packaging layer 110 is disposed in gaps between the plurality of connection units 100. The first packaging layer 110 may be in contact with at least a portion of surfaces of the plurality of connection units 100, such as side surfaces, thereby preventing the connection units 100 from being affected by external moisture, and thus improving the reliability of the connection units 100. The first packaging layer 110 may include any suitable packaging material, such as organic material, polymer, epoxy molding compound (EMC), silicone, silicon-containing material, glass packaging material, or nano-filler composite resin, but is not limited thereto. In some embodiments, the first packaging layer 110 may be formed by, for example, a deposition process or a molding process, but is not limited thereto.

Thereafter, after forming the first packaging layer 110, the release layer RL1 and the carrier Csub1 are removed by causing the release layer RL1 to lose adhesiveness. Then, the package structure 10 is flipped upside down and placed on a carrier Csub2 on which an anti-warpage layer WAL2 and a release layer RL2 are sequentially formed, with the first circuit structure CS1 facing upward and the first packaging layer 110 facing the carrier Csub2. The anti-warpage layer WAL2 may include materials as listed for the anti-warpage layer WAL1 above. The release layer RL2 may include materials as listed for the release layer RL1 above.

Next, conductive pillars WS1pbr are formed on the first circuit structure CS1. Then, a singulation process is performed along scribe lines SCL1 to form individual package structures 10. Then, after performing the singulation process, the release layer RL2 and the carrier Csub2 are removed by causing the release layer RL2 to lose adhesiveness (e.g., the package structure 10 shown in FIG. 3A). The conductive pillars WS1pbr may include any suitable conductive material, such as copper, titanium, nickel, combinations or alloys of the above materials, but are not limited thereto. In some embodiments, the conductive pillars WS1pbr may serve as portions for subsequently probing by the probes for the electrical testing.

Thereafter, referring to FIG. 3A, a second circuit structure CS2 is provided on a carrier Csub3 on which an anti-warpage layer WAL3, a release layer RL3, and a seed layer SL1 are sequentially formed. The material of the carrier Csub3 may include materials as listed for the carrier Csub1 above. The anti-warpage layer WAL3 may include materials as listed for the anti-warpage layer WAL1 above. The release layer RL3 may include materials as listed for the release layer RL1 above. The seed layer SL1 may include any suitable conductive material, such as titanium (Ti), titanium nitride (TiN), tungsten (W), nickel (Ni), tantalum (Ta), nitrides, carbides, other suitable metals, or alloys thereof or combinations of the aforementioned materials.

In this embodiment, the second circuit structure CS2 may include an insulation layer IL2 and a wiring structure WS2 formed in the insulation layer IL2. In some embodiments, the insulation layer IL2 may include a plurality of insulation layers alternately stacked along a vertical direction (e.g., Z direction). The wiring structure WS2 may include a plurality of conductive patterns/conductive layers and conductive vias formed in the insulation layer IL2 in which the conductive patterns/conductive layers are alternately stacked along the vertical direction, and the conductive vias connecting the conductive patterns/conductive layers. The wiring structure WS2 may include any suitable conductive material similar with the wiring structure WS1. In some embodiments, the conductive patterns/conductive layers in the wiring structure WS2 and the conductive vias connecting the conductive patterns/conductive layers may be formed by performing an electroplating process on the seed layer SL1 to grow the seed layer, but are not limited thereto. The insulation layer IL2 may include an organic material or an inorganic material similar with the insulation layer IL1.

Thereafter, as shown in FIG. 3A, a plurality of conductive vias TMV1, TMV2 are formed on the second circuit structure CS2. Next, as shown in FIG. 3A and FIG. 3B, the package structure 10 is bonded to the second circuit structure CS2 through alignment marks AM1, wherein the package structure 10 is electrically connected to the second circuit structure CS2. In this embodiment, since the conductive vias TMV1, TMV2 are first formed on the second circuit structure CS2 before the package structure 10 is bonded to the second circuit structure CS2, the impact of the process for forming the conductive vias TMV1, TMV2 on the package structure 10 may be reduced, thereby helping to improve the reliability of the package structure 10.

In some embodiments, the package structure 10 that meets the desired requirements after the electrical testing may be selectively bonded to the second circuit structure CS2, to help improve the yield and reliability of the interposer IP1 as disclosed herein, which may refer to FIG. 4 and FIG. 5A, but is not limited thereto. For example, the package structure 10 in the region R1 shown in FIG. 2 may be selectively bonded to the second circuit structure CS2.

In some embodiments, after forming the second circuit structure CS2, the second circuit structure CS2 may be electrically tested through probes to determine whether the second circuit structure CS2 meets desired requirements. For example, as shown in FIG. 3B, the second circuit structure CS2 may be a portion that meets desired requirements after electrical testing, while the second circuit structure CS2(NG) may be a portion that does not meet the desired requirements after the electrical testing. In some embodiments, the package structure 10 that meets desired requirements after electrical testing may be selectively bonded to the second circuit structure CS2 that meets the desired requirements after the electrical testing, to help improve the yield and reliability of the interposer IP1 as shown in FIG. 4.

In some other embodiments, the package structure 10 that does not meet desired requirements after electrical testing (such as the package structure 10 in the region R2(NG) shown in FIG. 2) may be selectively bonded to the second circuit structure CS2(NG) that does not meet the desired requirements after the electrical testing, such that the package structure 10, that does not meet the desired requirements after the electrical testing and is disposed on the second circuit structure CS2(NG), may serve as a support structure, thereby helping to improve process stability.

In some embodiments, the conductive vias TMV1, TMV2 may include through mold vias (TMV). The material of the conductive vias TMV1, TMV2 may include any suitable conductive material. In some embodiments, the conductive vias TMV1, TMV2 may be copper pillars formed on the second circuit structure CS2, but are not limited thereto. In some embodiments, the height of one of the plurality of conductive vias TMV1, TMV2 may be different from the height of another one of the plurality of conductive vias TMV1, TMV2, which is beneficial for improving the warpage degree of the interposer IP1. In this embodiment, “the height of one component” may refer to the maximum height of the component measured in the vertical direction (e.g., Z direction). For example, the height H2 of the conductive via TMV2 may be greater than the height H1 of the conductive via TMV1. The conductive vias disclosed herein include copper pillars that penetrate through the second packaging layer ML1 and extend to a portion of the second circuit structure CS2.

In this embodiment, the package structure 10 may be bonded to the second circuit structure CS2 through connection elements CE2 disposed between the conductive elements 108 and the pads WS2p. The material of the connection elements CE2 may include suitable materials similar with the connection elements CE1. In some embodiments, the connection elements CE2 may include solder balls.

In this embodiment, the conductive pillars WS1pbr of the package structure 10 may serve as portions for probing by the probes to perform electrical testing, such that, after the package structure 10 is disposed on the second circuit structure CS2, the electrical testing may be performed by probing the conductive pillars WS1pbr with the probes to determine whether the electrical connection between the package structure 10 and the second circuit structure CS2 meets desired requirements (i.e., whether the formed interposer IP1 meets the desired requirements in the electrical testing). For example, as shown in FIG. 4, the interposer IP1 in the region R1 may be a region that meets desired requirements in electrical testing, while the interposer IP1 in the region R2(NG) may be a region that does not meet the desired requirements in the electrical testing.

Thereafter, referring to both FIG. 3A and FIG. 4, a second underfill UF2 is provided between the second circuit structure CS2 and the first packaging layer 110 to ensure signal transmission paths between the package structure 10 and the second circuit structure CS2, thereby helping to improve the reliability of the electronic device. In this embodiment, the second underfill UF2 may surround the connection elements CE2 and the pads WS2p. In this embodiment, “one component surrounds another component” may mean that the component may be at least in contact with the side surfaces of another component in a cross-sectional view. For example, as shown in FIG. 4, the second underfill UF2 may be in contact with the side surfaces of the connection elements CE2 and the pads WS2p.

In this embodiment, as shown in FIG. 4, the region R1 may be a region where the interposer IP1 meets desired requirements in electrical testing, while the region R2 (NG) may be a region where the interposer IP1 does not meet desired requirements in electrical testing. In this case, the second underfill UF2 may be formed only in the region R1 that meets the desired requirements, and may not be formed in the region R2 (NG) that does not meet the desired requirements, which is beneficial for saving process costs.

Then, referring to FIG. 3A and FIG. 4, a second packaging layer ML1 surrounding the package structure 10 is formed on the second circuit structure CS2. The second packaging layer ML1 may prevent the package structure 10 and the conductive vias TMV1, TMV2 from being affected by external moisture, thereby improving the reliability of the interposer IP1. The second packaging layer ML1 may include any suitable packaging material similar with the first packaging layer 110. In some embodiments, the second packaging layer ML1 may be formed by, for example, a deposition process or a molding process, but is not limited thereto.

Thereafter, a singulation process is performed along a scribe line SCL2 to form individual interposers IP1. Then, after performing the singulation process, the release layer RL3 and the carrier Csub3 are removed by causing the release layer RL3 to lose adhesiveness, and then the seed layer SL1 is removed by any suitable process to form the interposer IP1 as shown in FIG. 5A.

Hereinafter, the interposer IP1 according to this embodiment will be described through FIG. 5A and FIG. 5B. Although the interposer IP1 of this embodiment is formed by the method described above, it is not limited thereto.

Referring to FIG. 5A, the interposer IP1 includes a package structure 10. The package structure 10 includes a plurality of connection units 100, a first packaging layer 110, and a first circuit structure CS1. The plurality of connection units 100 are spaced apart from each other and arranged in an array (as shown in FIG. 5B), that is, in a top view direction, the plurality of connection units 100 may be arranged along the X direction or the Y direction. Each connection unit 100 includes a substrate layer 102 and a first conductive element 104 disposed in the substrate layer 102. In this embodiment, one of the plurality of connection units 100 may include conductive elements 106 and conductive elements 108 respectively disposed at opposite sides of the substrate layer 102, wherein the first conductive elements 104 may penetrate through the substrate layer 102 to connect the conductive elements 106 to the conductive elements 108. The first packaging layer 110 encapsulates the connection units 100 and includes portions disposed between the connection units 100. The first circuit structure CS1 is disposed at a first side 110S1 of the first packaging layer 110 and electrically connected to the plurality of connection units 100.

In this embodiment, the interposer IP1 further includes a second circuit structure CS2 disposed on the package structure 10, and the second circuit structure CS2 may be electrically connected to at least one of the plurality of connection units 100. In this embodiment, the second circuit structure CS2 may be disposed at a second side 110S2 of the first packaging layer 110 opposite to the first side 110S1. The second circuit structure CS2 may be electrically connected to the first circuit structure CS1 through at least one of the plurality of connection units 100. In this embodiment, the interposer IP1 further includes a second packaging layer ML1 disposed at a first side of the second circuit structure CS2 and surrounding the package structure 10, wherein the first side of the second circuit structure CS2 is adjacent to the second side 110S2 of the first packaging layer 110. The interposer IP1 further includes a plurality of conductive vias TMV1, TMV2 penetrating through the second packaging layer ML1 and electrically connected to the second circuit structure CS2. In this embodiment, a height of one of the plurality of conductive vias TMV1, TMV2 may be different from a height of another one of the plurality of conductive vias TMV1, TMV2. For example, the height H2 of the conductive via TMV2 may be greater than the height H1 of the conductive via TMV1.

In this embodiment, the plurality of connection units 100 may be spaced apart from each other by a spacing, such that portions of the first packaging layer 110 are disposed in the spacing, to help mitigate the difference in coefficient of thermal expansion (CTE) between the connection units 100 and the second circuit structure CS2, thereby improving the reliability of the interposer IP1 and/or the reliability of the electronic device ED1 including the interposer IP1. In some embodiments, the plurality of connection units 100 may have a spacing of about 20 μm to about 1000 μm, or 50 μm to about 800 μm, or 100 μm to about 500 μm between them.

In this embodiment, the package structure 10 further includes a first underfill UF1 disposed between the first circuit structure CS1 and the first packaging layer 110. In this embodiment, the interposer IP1 further includes a second underfill UF2 disposed between the second circuit structure CS2 and the first packaging layer 110. According to some embodiments, the first underfill UF1 and the second underfill UF2 are insulation materials, which may include organic materials, inorganic materials, or combinations thereof. The thickness variance of the first underfill UF1 and the second underfill UF2 is smaller than the thickness variance of the first packaging layer 110, thereby improving the quality of subsequent processes or enhancing the electrical performance of the electronic device. The thickness variance referred to in this disclosure may be obtained by measuring the thickness (xᵢ) at different positions (at least five (N) different positions) and obtaining the average thickness (μ) of the thicknesses at these different positions, and then calculating the thickness variance through a variance formula (such as Formula 1 below).

$$Var ( X ) = {σ}^{2} = \frac{{\sum }_{i = 1}^{N} {( {x}_{i} - μ )}^{2}}{N} \qquad [ Formula 1 ]$$

In Formula 1, Var(X) represents variance, σ² represents population variance, N represents population size, xᵢ represents the i-th data point in the population, and μ represents population mean.

Hereinafter, the electronic device ED1 according to this embodiment will be described through FIG. 5A and FIG. 5B, wherein the same or similar components are represented by the same or similar reference numerals or symbols, and will not be repeatedly described here.

Referring to FIG. 5A, the electronic device ED1 includes an interposer IP1, a plurality of electronic units EU1, and an external component 200.

The interposer IP1 includes a package structure 10 and a second circuit structure CS2. The package structure 10 includes a plurality of connection units 100, a first packaging layer 110, and a first circuit structure CS1. The plurality of connection units 100 are spaced apart from each other and arranged in an array (as shown in FIG. 5B). Each connection unit 100 includes a substrate layer 102 and a first conductive element 104 disposed in the substrate layer 102. In this embodiment, one of the plurality of connection units 100 may include second conductive elements 106 and second conductive elements 108 respectively disposed on opposite sides of the substrate layer 102, wherein the first conductive elements 104 may penetrate through the substrate layer 102 to connect the second conductive elements 106 to the second conductive elements 108. The first packaging layer 110 encapsulates the plurality of connection units 100 and includes portions disposed between the plurality of connection units 100. The first circuit structure CS1 is disposed on a first side of the first packaging layer 110 and electrically connected to the plurality of connection units 100. In this embodiment, the package structure 10 further includes a first underfill UF1 disposed between the first circuit structure CS1 and the first packaging layer 110. The second circuit structure CS2 is disposed on a second side of the first packaging layer 110 opposite to the first side and electrically connected to the plurality of connection units 100.

In this embodiment, the interposer IP1 further includes a second packaging layer ML1 disposed under the second circuit structure CS2 and surrounding the package structure 10, and a plurality of conductive vias TMV1, TMV2 penetrating through the second packaging layer ML1 and electrically connecting the second circuit structure CS2 to the external component 200. In this embodiment, a height of one of the plurality of conductive vias TMV1, TMV2 may be different from a height of another one of the plurality of conductive vias TMV1, TMV2. In this embodiment, the interposer IP1 further includes a second underfill UF2 disposed between the second circuit structure CS2 and the first packaging layer 110.

The plurality of electronic units EU1 are disposed on the second circuit structure CS2 and electrically connected to the second circuit structure CS2. The electronic unit EU1 may include a central processing unit (CPU), a graphics processing unit (GPU), or a memory such as three-dimensional high bandwidth memory (HBM), but is not limited thereto. The plurality of electronic units EU1 may be the same as or different from each other. In this embodiment, as shown in FIG. 5B, the plurality of electronic units EU1 may be arranged on the second circuit structure CS2 of the interposer IP1 in an array.

The external component 200 is disposed under the first circuit structure CS1 and electrically connected to the first circuit structure CS1. In some embodiments, the external component 200 may be a circuit substrate (such as a printed circuit board), but is not limited thereto.

In this embodiment, the external component 200 may be connected to the first circuit structure CS1 through connection elements CE3 disposed between the external component 200 and the first circuit structure CS1. In this embodiment, the plurality of electronic units EU1 may be connected to the second circuit structure CS2 through connection elements CE4 disposed between the plurality of electronic units EU1 and the second circuit structure CS2. The connection elements CE3 and the connection elements CE4 may each include suitable materials similar with the connection elements CE1. In some embodiments, the connection elements CE3 or the connection elements CE4 may include solder balls or micro bumps.

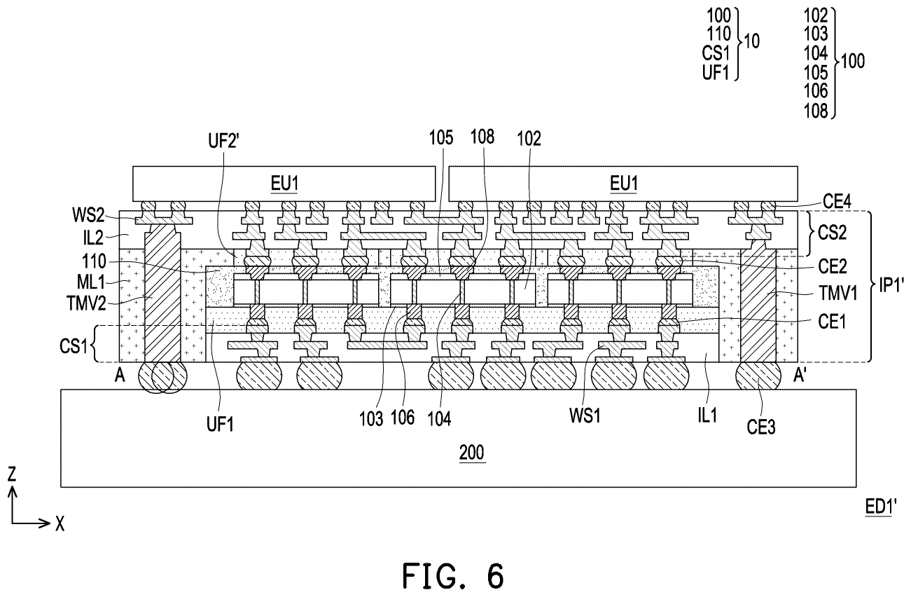

FIG. 6 is a schematic cross-sectional view of an electronic device according to a second embodiment of the present disclosure. The interposer IP1′ of the electronic device ED1′ shown in FIG. 6 is similar to the interposer IP1 of the electronic device ED1 shown in FIG. 5A, with the main difference being that the second underfill UF2′ shown in FIG. 6 is different from the second underfill UF2 shown in FIG. 5A. The remaining same or similar components are represented by the same or similar reference numerals or symbols and will not be repeatedly described herein.

As shown in FIG. 6, the second underfill UF2′ of the interposer IP1′ may be plural and respectively disposed between the second circuit structure CS2 and the substrate layer 102, wherein the second packaging layer ML1 may surround the plurality of second underfills UF2′, which may further reduce the difference in coefficient of thermal expansion (CTE) between the substrate layer 102 of the connection unit 100 and other various electronic elements and/or various packages including the various electronic elements (such as the difference in CTE between the electronic unit EU1 and the external component 200), thereby helping to improve the reliability of the interposer IP1′ and/or the electronic device ED1′ including the interposer IP1′.

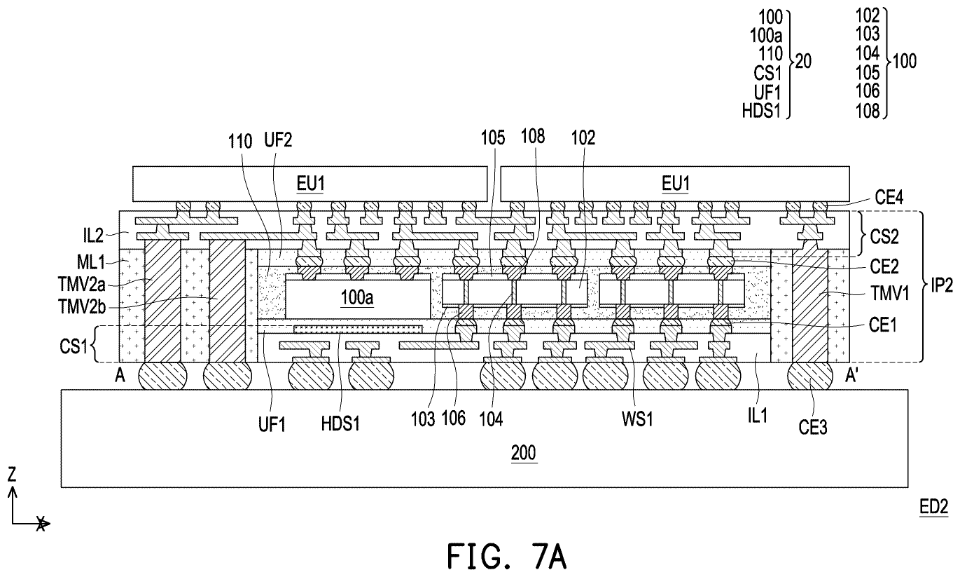

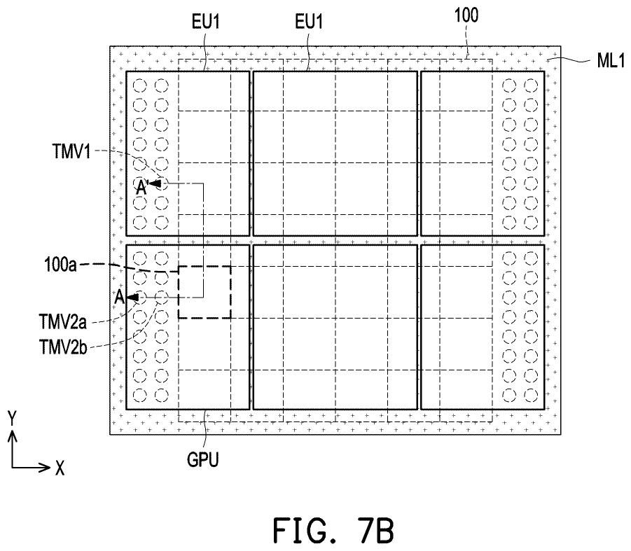

FIG. 7A and FIG. 7B are respectively a schematic cross-sectional view and a schematic top view of an electronic device according to a third embodiment of the present disclosure. FIG. 7B is a schematic top view in an embodiment of FIG. 7A, for example, FIG. 7A is corresponded to a schematic cross-sectional view taken along line A-A′ in FIG. 7B. For the convenience of illustration, FIG. 7B merely shows the connection unit 100, the electronic unit EU1, the second packaging layer ML1, and the conductive vias TMV1, TMV2a, TMV2b. The interposer IP2 of the electronic device ED2 shown in FIG. 7A is similar to the interposer IP1 of the electronic device ED1 shown in FIG. 5A, with the main difference being that the package structure 20 shown in FIG. 7A includes an electronic element 100a and a heat dissipation structure HDS1. The remaining same or similar components are represented by the same or similar reference numerals or symbols and will not be repeatedly described herein.

Referring to FIG. 7A, the package structure 20 may include an electronic element 100a arranged together with the plurality of connection units 100 in an array (as shown in FIG. 7B), that is, the electronic element 100a may be integrated in the interposer IP2 to help improve the element integration of the electronic device ED2. The electronic element 100a may include various active elements or passive elements. For example, the electronic element 100a may include elements such as capacitors, resistors, inductors, diodes, transistors, or combinations thereof, but are not limited thereto. In some embodiments, the electronic element 100a may include power management integrated circuit (PMIC) chips to help reduce the power consumption of the electronic device ED2. In some other embodiments, the electronic element 100a may also include chips with other functions, such as logic chips, memory chips, or sensing chips. In some alternative embodiments, the electronic element 100a may also include DC-DC converters, regulators, or combinations thereof. In some embodiments, the regulators may include linear regulators, low dropout linear regulators (LDO), or the like.

In the present embodiment, the package structure 20 may include a heat dissipation structure HDS1 disposed in the first circuit structure CS1, and the heat dissipation structure HDS1 may overlap with the electronic element 100a, which may help transfer heat generated by the electronic element 100a through the heat dissipation structure HDS1 and other wiring structures in the first circuit structure CS1 for establishing heat transfer paths to other components (such as the external component 200). The heat dissipation structure HDS1 may include any suitable thermally conductive material such as gold, silver, copper, or aluminum, but is not limited thereto. In some embodiments, the heat dissipation structure HDS1 may be integrated in the manufacturing process for forming the first circuit structure CS1.

In the present embodiment, the electronic element 100a may be thermally coupled to the heat dissipation structure HDS1. In the present embodiment, “thermal coupling” refers to the connection of two objects such that heat energy may be transferred between them, which may include the following aspects: direct contact between the two objects or indirect contact where the two objects are separated by a thermally conductive material. In the present embodiment, “one component overlapped with another component” may refer to the component overlapped with another component in a top view direction (e.g., in the Z direction) of the electronic device ED2.

In the present embodiment, the height of the conductive via TMV1 may be different from the heights of the conductive vias TMV2a and TMV2b, and the height of the conductive via TMV2a may be approximately equal to the height of the conductive via TMV2b.

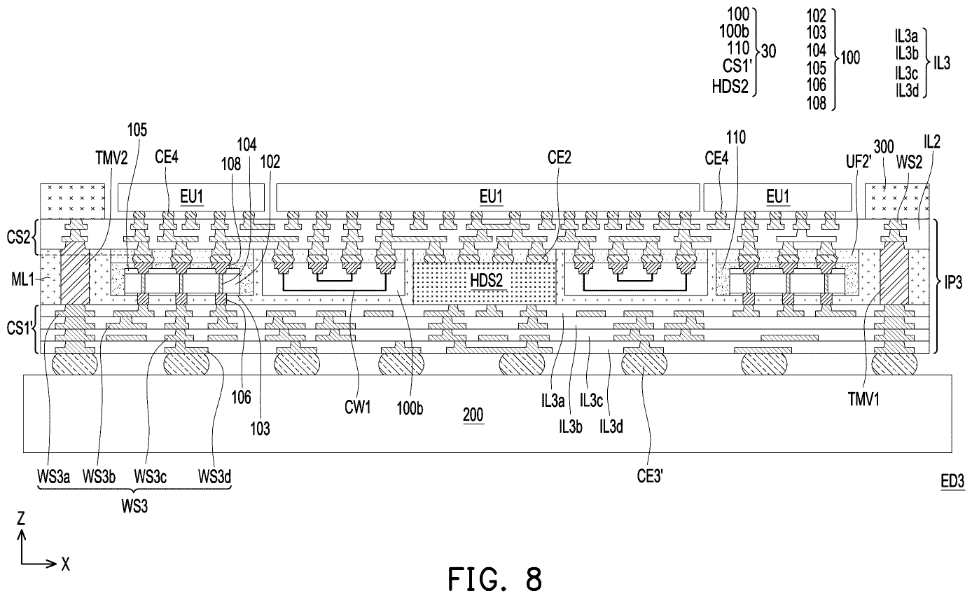

FIG. 8 is a schematic cross-sectional view of an electronic device according to a fourth embodiment of the present disclosure. The interposer IP3 of the electronic device ED3 shown in FIG. 8 is similar to the interposer IP1 of the electronic device ED1 shown in FIG. 5A, with the main difference being that the package structure 30 shown in FIG. 8 is different from the package structure 10 shown in FIG. 5A. The remaining same or similar components are represented by the same or similar reference numerals or symbols and will not be repeatedly described herein.

Referring to FIG. 8, in the package structure 30, one of the plurality of connection units 100 may include a plurality of second conductive elements disposed at one side of the substrate layer 102, wherein the first conductive element disposed in the substrate layer 102 may include a connection wiring connecting the second conductive elements. For example, the connection unit 100b may include a plurality of conductive elements 108 disposed at one side of the substrate layer 102, wherein the conductive element disposed in the substrate layer 102 may include the connection wiring CW1 connecting the conductive elements 108, which may satisfy electronic units having a high number of input/output pads (I/O pads). For example, when the electronic unit EU1 at the center of FIG. 8 is a graphics processing unit (GPU), the connection units 100 of the interposer IP3 that are located below the GPU may be replaced with the connection units 100b to satisfy the large number of I/O pads required by the GPU. Based on the above, the interposer IP3 may implement different connection manners in different regions according to requirements. In other words, the interposer IP3 may match different types of connection units according to different types of electronic units, enabling the interposer IP3 to be easily integrated into various products. In some embodiments, the connection unit 100b may be a silicon bridge. The connection wiring CW1 may include any suitable conductive material, such as copper, titanium, nickel, gallium (Ga), ruthenium (Ru), tantalum (Ta), combinations or alloys of the above materials, but is not limited thereto.

In some embodiments, the package structure 30 may include a heat dissipation structure HDS2 arranged together with the plurality of connection units 100, 100b in an array. In this embodiment, the heat dissipation structure HDS2 may be placed below the electronic unit EU1 that requires more heat dissipation requirements. For example, when the electronic unit EU1 at the center of FIG. 8 is a graphics processing unit (GPU), the connection unit 100 of the interposer IP3 that is located below the GPU may be replaced with the heat dissipation structure HDS2 to satisfy the heat dissipation requirements of the GPU. In some embodiments, the heat dissipation structure HDS2 may include materials having high thermal conductivity and low CTE to achieve good heat transfer while mitigating the CTE difference between the heat dissipation structure HDS2 and the second circuit structure CS2 and/or the external component 200. For example, the heat dissipation structure HDS2 may include ceramic materials (such as AlSiC, SiC, or AlN), alloy materials (such as invar alloy, also known as nickel-steel alloy), or carbon materials having specific thermal conduction directions or good thermal conductivity (such as graphene, carbon nanotubes, or diamond), or combinations thereof.

In this embodiment, the first circuit structure CS1′ in the package structure 30 may include Ajinomoto build-up film (ABF), in such case, the first circuit structure CS1′ may include a plurality of insulation layers IL3a, IL3b, IL3c, IL3d alternately stacked along a vertical direction (such as Z direction). The wiring structure WS3 may include a plurality of wiring layers WS3a, WS3b, WS3c, WS3d respectively formed in the insulation layers IL3a, IL3b, IL3c, IL3d and alternately stacked along the vertical direction.

In some embodiments, the interposer IP3 may be formed by the following method. First, a plurality of connection units 100 are bonded on the second circuit structure CS2. Next, a plurality of conductive vias TMV1, TMV2 are formed on the second circuit structure CS2. Then, a second underfill UF2′ is provided between the second circuit structure CS2 and the first packaging layer 110. Subsequently, a second packaging layer ML1 surrounding the package structure 30 is formed on the second circuit structure CS2. Thereafter, a first circuit structure CS1′ is formed on the second packaging layer ML1. Subsequently, a singulation process is performed to form the interposer IP3 as shown in FIG. 8.

In some embodiments, the electronic device ED3 may further include a stiffener structure 300 disposed on the second circuit structure CS2 and surrounding the plurality of electronic units EU1. In some embodiments, the conductive vias TMV1, TMV2 may be thermally coupled to the stiffener structure 300, such that heat generated by the electronic units EU1 (such as the electronic unit EU1 at the center in FIG. 8) may be transferred to the conductive vias TMV1, TMV2 through the heat dissipation structure HDS2 below and the wiring layers serving as heat transfer paths in the first circuit structure CS1′, and then transferred to the stiffener structure 300, which may help improve the heat dissipation efficiency of the electronic device ED3, enabling the electronic units EU1 to have desired performance and/or stability.

In some embodiments, the stiffener structure 300 may be a stiffener ring surrounding the plurality of electronic units EU1. In this embodiment, the stiffener structure 300 may include any suitable thermally conductive material (such as copper) to improve the heat dissipation efficiency of the electronic device ED3.

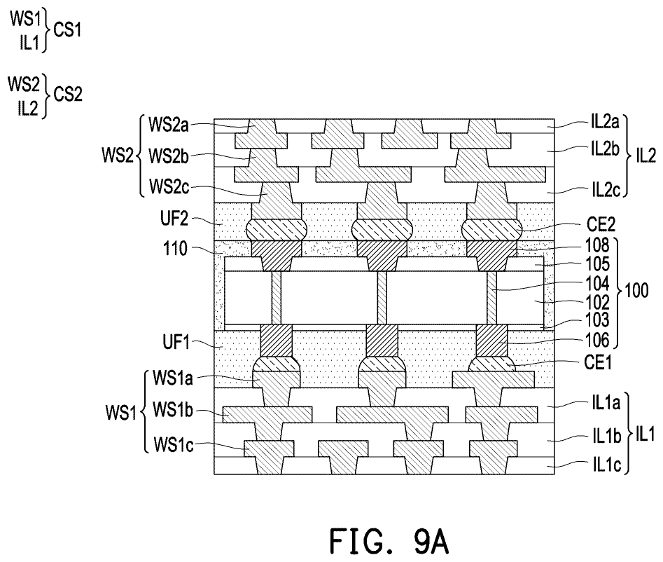

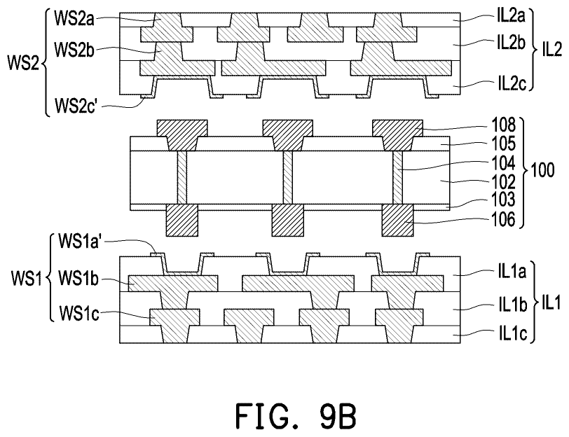

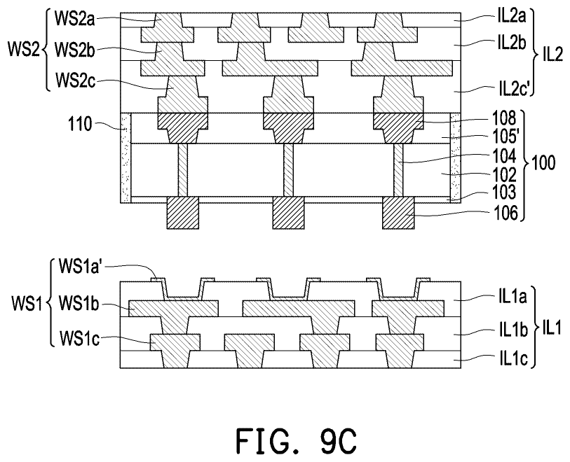

FIG. 9A to FIG. 9C are schematic cross-sectional views of interposers according to different embodiments of the present disclosure. FIG. 9A to FIG. 9C illustrate different connection manners between the connection unit 100 and the first circuit structure CS1 and between the connection unit 100 and the second circuit structure CS2.

Referring to FIG. 9A, the first circuit structure CS1 may include a plurality of insulation layers IL1a, IL1b, IL1c alternately stacked along a vertical direction (such as the Z direction). The wiring structure WS1 may include a plurality of wiring layers WS1a, WS1b, WS1c respectively formed in the insulation layers IL1a, IL1b, IL1c and alternately stacked along the vertical direction. The second circuit structure CS2 may include a plurality of insulation layers IL2a, IL2b, IL2c alternately stacked along the vertical direction (such as the Z direction). The wiring structure WS2 may include a plurality of wiring layers WS2a, WS2b, WS2c respectively formed in the insulation layers IL2a, IL2b, IL2c and alternately stacked along the vertical direction. In this embodiment, the connection unit 100 may be bonded to the first circuit structure CS1 and the second circuit structure CS2 through the connection elements CE1 and the connection elements CE2, respectively, wherein the first underfill UF1 may be provided between the substrate layer 102 of the connection unit 100 and the first circuit structure CS1 to surround the connection elements CE1, and the second underfill UF2 may be provided between the connection unit 100 and the second circuit structure CS2 to surround the connection elements CE2.

Referring to FIG. 9B, the wiring layers WS1a′ and WS2c′ adjacent to the connection unit 100 may be formed as patterns with grooves, such as groove-type under-bump metallization (UBM), which may help improve the bonding stability between the conductive elements 106, 108 and the wiring layers WS1a′, WS2c′, and may also selectively omit the first underfill UF1 and the second underfill UF2 to help reduce process costs.

Referring to FIG. 9C, in this embodiment, the second circuit structure CS2 may be bonded to the connection unit 100 through a manner of hybrid bonding, while the first circuit structure CS1 may be bonded to the connection unit 100 by designing the wiring layer WS1a′ adjacent to the connection unit 100 as a pattern with grooves (such as groove-type UBM). In this embodiment, the insulation layer 105′ may have a top surface with substantially the same horizontal height as the conductive element 108, and the insulation layer IL2c′ may have a top surface with substantially the same horizontal height as the wiring layer WS2c, such that the bonding interface between the second circuit structure CS2 and the connection unit 100 may include metal-to-metal bonding between the conductive element 108 and the wiring layer WS2c, and oxide-to-oxide bonding or polyimide-to-polyimide bonding between the insulation layer 105′ and the insulation layer IL2c′. “Substantially the same” as referred to in the present disclosure means that the height difference in the Z direction between adjacent surfaces of two elements is less than or equal to 10 μm.

In summary, in the embodiments of the present disclosure, the first packaging layer encapsulates a plurality of connection units that are spaced apart from each other and arranged in an array and includes portions disposed between the plurality of connection units, which may mitigate the difference in coefficient of thermal expansion (CTE) between the substrate layer of the connection units and other various electronic elements and/or various packages including the various electronic elements, thereby helping to improve the reliability of the interposer and/or the electronic device containing the interposer.

In summary, in the manufacturing method of the electronic device provided by some embodiments of the disclosure, by simultaneously cutting the build-up structure located on both sides of the substrate, the possibility of technical problems such as warpage and/or cracking of the substrate due to stress mismatch may be reduced, thereby improving the yield and/or reliability of the manufactured electronic device.

What is claimed is:

1. An interposer, comprising:
a package structure, comprising:
a plurality of connection units spaced apart from each other and arranged in an array, wherein each of the connection units comprises a substrate layer and a first conductive element disposed in the substrate layer;
a first packaging layer surrounding the plurality of connection units and comprising a portion disposed between the plurality of connection units; and
a first circuit structure disposed at a first side of the first packaging layer and electrically connected to the plurality of connection units.

2. The interposer according to claim 1, further comprising:
a second circuit structure disposed at a second side of the first packaging layer opposite to the first side and electrically connected to at least one of the plurality of connection units.

3. The interposer according to claim 2, further comprising:
a second packaging layer disposed at a first side of the second circuit structure adjacent to the second side of the first packaging layer and surrounding the package structure; and
a plurality of conductive vias penetrating through the second packaging layer and electrically connected to the second circuit structure.

4. The interposer according to claim 3, wherein a height of one of the plurality of conductive vias is different from a height of another one of the plurality of conductive vias.

5. The interposer according to claim 3, wherein the package structure comprises a first underfill disposed between the first circuit structure and the first packaging layer.

6. The interposer according to claim 5, further comprising:
a plurality of second underfills disposed between the second circuit structure and the substrate layer, wherein the second packaging layer surrounds the plurality of second underfills.

7. The interposer according to claim 1, wherein the package structure comprises an electronic element arranged together with the plurality of connection units in the array.

8. The interposer according to claim 7, wherein the package structure comprises a heat dissipation structure disposed in the first circuit structure, and the heat dissipation structure overlaps with the electronic element.

9. The interposer according to claim 1, wherein the package structure comprises a heat dissipation structure arranged together with the plurality of connection units in the array.

10. The interposer according to claim 1, wherein one of the plurality of connection units comprises a plurality of second conductive elements respectively disposed on opposite sides of the substrate layer, wherein the first conductive element penetrates through the substrate layer to connect the plurality of second conductive elements.

11. The interposer according to claim 1, wherein one of the plurality of connection units comprises a plurality of second conductive elements disposed at one side of the substrate layer, wherein the first conductive element comprises a connection wiring connecting the plurality of second conductive elements.

12. An electronic device, comprising:
an interposer, comprising:
a package structure, comprising:
a plurality of connection units spaced apart from each other and arranged in an array, wherein each connection unit comprises a substrate layer and a first conductive element disposed in the substrate layer;
a first packaging layer encapsulating the plurality of connection units and comprising a portion disposed between the plurality of connection units; and
a first circuit structure disposed at a first side of the first packaging layer and electrically connected to the plurality of connection units; and
a second circuit structure disposed at a second side of the first packaging layer opposite to the first side and electrically connected to the plurality of connection units;
a plurality of electronic units disposed on the second circuit structure and electrically connected to the second circuit structure; and
an external component disposed under the first circuit structure and electrically connected to the first circuit structure.

13. The electronic device according to claim 12, wherein the interposer comprises:
a second packaging layer disposed under the second circuit structure and surrounding the package structure; and
a plurality of conductive vias penetrating through the second packaging layer and electrically connecting the second circuit structure to the external component.

14. The electronic device according to claim 13, wherein a height of one of the plurality of conductive vias is different from a height of another one of the plurality of conductive vias.

15. The electronic device according to claim 13, wherein the package structure comprises a first underfill disposed between the first circuit structure and the first packaging layer, and
the interposer comprises a plurality of second underfills disposed between the second circuit structure and the substrate layer, wherein the second packaging layer surrounds the plurality of second underfills.

16. The electronic device according to claim 12, wherein the package structure comprises an electronic element arranged together with the plurality of connection units in the array.

17. The electronic device according to claim 16, wherein the package structure comprises a heat dissipation structure disposed in the first circuit structure and overlapped with the electronic element.

18. The electronic device according to claim 12, wherein the package structure comprises a heat dissipation structure arranged together with the plurality of connection units in the array.

19. The electronic device according to claim 12, further comprising:
a stiffener structure disposed on the second circuit structure and surrounding the plurality of electronic units.

20. A method for manufacturing an interposer, comprising:
arranging a plurality of connection units on a first circuit structure in an array, wherein the plurality of connection units are electrically connected to the first circuit structure, and each connection unit comprises a substrate layer and a first conductive element disposed in the substrate layer;
providing a first underfill between the first circuit structure and the substrate layer; and
providing a first packaging layer encapsulating the plurality of connection units on the first underfill to form a package structure, wherein the first packaging layer comprises a portion formed between the plurality of connection units.
